(19) United States
(12) Patent Application Publication
(10) Pub. No.: US 2012/0139089 A1
(43) Pub. Date: Jun. 7, 2012

(54) MODULE IC PACKAGE STRUCTURE AND METHOD FOR MAKING THE SAME

(75) Inventors: CHUNG-ER HUANG, NEW TAIPEI CITY (TW); MING-TAI KUO, NEW TAIPEI CITY (TW)

(73) Assignee: AZUREWAVE TECHNOLOGIES, INC., NEW TAIPEI CITY (TW)

(21) Appl. No.: 13/005,084

(22) Filed: Jan. 12, 2011

(30) Foreign Application Priority Data
Dec. 3, 2010 (TW) 99142102

(51) Int. Cl. H01L 23/552; H01L 21/50

(52) U.S. Cl. 257/659; 438/124; 257/E23.114; 257/E21.499

(57) ABSTRACT

A module IC package structure includes a substrate unit, an electronic unit, a conductive unit, a package unit and a shielding unit. The substrate unit includes a circuit substrate having at least one grounding pad. The electronic unit includes a plurality of electronic elements electrically connected to the circuit substrate. The conductive unit includes at least one elastic conductive element disposed on the circuit substrate, and the elastic conductive element has a first end portion electrically connected to the grounding pad. The package unit includes a package resin body disposed on the circuit substrate to cover the electronic elements and one part of the elastic conductive element, and the elastic conductive element has a second end portion is exposed from the package resin body. The shielding unit includes a metal shielding layer formed on the outer surface of the package resin body to electrically contact the second end portion.

### BACKGROUND OF THE INVENTION

1. Field of the Invention

The instant disclosure relates to a module IC (integrated circuit) package structure and a method for making the same, and more particularly, to a module IC package structure with electrical shield function and a method for making the same.

2. Description of Related Art

As integrated circuit technology has been rapidly developing, a variety of devices using the technology are developed continuously. Because the functions of the devices are rapidly added, most devices are implemented in a modular way. However, while the functions of the devices can be increased by integrating a lot of functional modules, the design of a multiple function device with small dimensions is still difficult.

In the semiconductor manufacturing process, a high level technology is used to manufacture a small chip or component. Therefore, the module manufacturer can design a functional module with small dimensions, and the device can be efficiently and fully developed. Currently, most modules use the printed circuit board (PCB), Flame Retardant 4 (FR-4), or Bismaleimide Triazine (BT) substrate as a carrier. All chips and components are mounted onto the surface of the carrier by using a surface mounting technology (SMT). Therefore, the substrate is merely used as a carrier and is used for connecting the circuit. The structure of the substrate is a multiple-layered structure and is only used for the circuit layout.

Following the development of radio frequency technology, wireless communication systems are becoming more powerful and their performance increases. Demands on these systems are low weight, small dimensions, high quality, low energy-consumption high reliability, and low manufacturing costs. Another important function of wireless communication systems is the electric shielding of radiation emitted by their components in order to minimize interference of this radiation with other electronic devices or components.

However, up to the present the production of the shielding structures adds disproportional costs and time expenditure to the total manufacturing costs. In many cases the shielding structure is realized as a sheet steel casing around the wireless device or circuit module, necessitating the manufacture of costly dies for each shielding structure shape. Another currently employed method is to produce the casings by metal casting. In this case each shape to be cast requires the manufacture of a specific casting mold which involves manual work, leading to high costs. Furthermore, the assembly of the metal casings and the circuit modules is usually performed manually thus further increases costs.

Therefore, in light of the above mentioned shortcomings of the present state of the art, the inventor proposes the present invention to overcome the above problems based on his expert experience and research.

### SUMMARY OF THE INVENTION

One particular aspect of the instant disclosure is to provide a module IC package structure and a method for making the same to generate an electrical shield function for electronic elements.

To achieve the above-mentioned advantages, one embodiment of the instant disclosure provides a module IC package structure with electrical shield function and a method for making the same. The module IC package structure comprises a substrate unit, an electronic unit, a conductive unit, a package unit and a shielding unit. The substrate unit includes at least one circuit substrate having at least one grounding pad. The electronic unit includes a plurality of electronic elements disposed on and electrically connected to the circuit substrate. The conductive unit includes at least one elastic conductive element disposed on the circuit substrate, and the elastic conductive element has a first end portion electrically connected to the grounding pad. The package unit includes a package resin body disposed on the circuit substrate to cover the electronic elements and one part of the elastic conductive element, and the elastic conductive element has a second end portion is exposed. The shielding unit includes a metal shielding layer formed on the outer surface of the package resin body to electrically contact the second end portion of the elastic conductive element.

To achieve the above-mentioned advantages, one embodiment of the instant disclosure provides a method for making a module IC package structure with electrical shield function, comprising the steps of: providing at least one circuit substrate having at least one grounding pad; placing a plurality of electronic elements on the circuit substrate to electrically connect to the circuit substrate; placing at least one elastic conductive element on the circuit substrate, wherein the elastic conductive element has a first end portion electrically connected to the grounding pad and a second end portion; forming a package resin body on the circuit substrate to cover the electronic elements and one part of the elastic conductive element, wherein the top surface of the second end portion of the elastic conductive element is exposed from the package resin; and forming a metal shielding layer on the outer surface of the package resin body and the top surface of the second end portion of the elastic conductive element to electrically contact the second end portion of the elastic conductive element.

Therefore, the metal shielding layer on the package resin body can electrically contact the grounding pad of the circuit substrate through the at least one elastic conductive element, thus the instant disclosure can generate the electrical shield function to prevent the electronic elements from being interfered by external environment.

To further understand the techniques, means and effects the instant disclosure takes for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention that they be used for limiting the instant disclosure.

### BRIEF DESCRIPTION OF THE DRAWINGS

FIG. 1 shows a flowchart of the method for making a module IC package structure according to the first embodiment of the instant disclosure;

FIG. 1A shows a perspective, schematic view from the step S100 to the step S104 according to the first embodiment of the instant disclosure;

FIG. 1B shows a cross-sectional view along line 1B-1B in FIG. 1A;

FIG. 1C shows a perspective, schematic view of the step S106 according to the first embodiment of the instant disclosure;

FIG. 1D shows a cross-sectional view along line 1D-1D in FIG. 1C;

FIG. 1E shows a perspective, schematic view of the step S108 according to the first embodiment of the instant disclosure;

FIG. 1F shows a cross-sectional view along line 1E-1E in FIG. 1E;

FIG. 1G shows a perspective, schematic view of the step S110 according to the first embodiment of the instant disclosure;

FIG. 1H shows a cross-sectional view along line 1H-1H in FIG. 1G;

FIG. 2A shows a flowchart of the method for making a module IC package structure according to the second embodiment of the instant disclosure;

FIG. 2B(A-D) shows cross-sectional, schematic views of the module IC package structure according to the second embodiment of the instant disclosure, at different stages of the packaging processes, respectively;

FIG. 3A shows a flowchart of the method for making a module IC package structure according to the third embodiment of the instant disclosure;

FIG. 3B(A-D) shows cross-sectional, schematic views of the module IC package structure according to the third embodiment of the instant disclosure, at different stages of the packaging processes, respectively;

FIG. 4A shows a perspective, schematic view of the spiral conductive element of the instant disclosure; and

FIG. 4B shows a front, schematic view of the spiral conductive element of the instant disclosure.

### DETAILED DESCRIPTION OF THE PREFERRED EMBODIMENTS

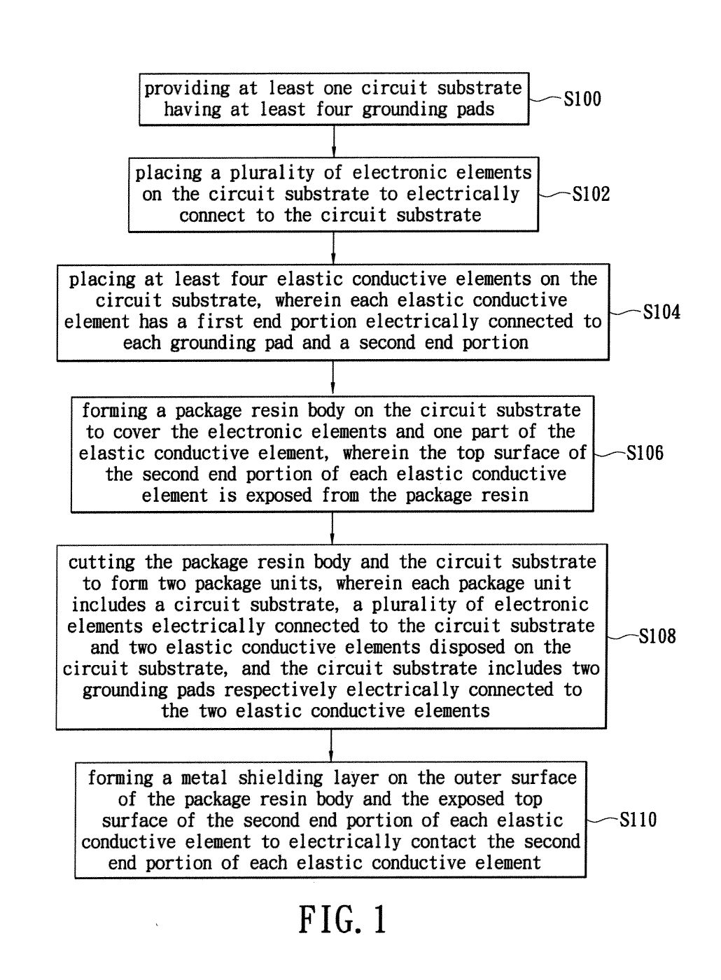

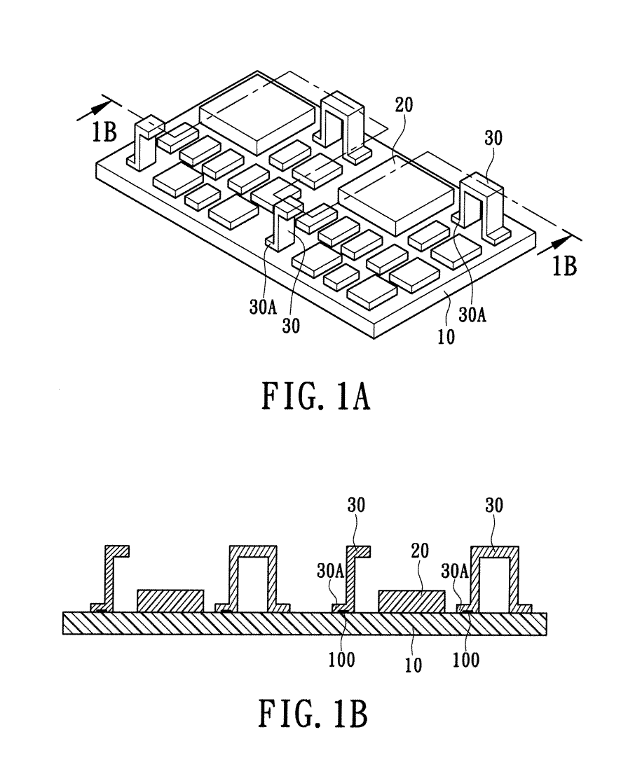

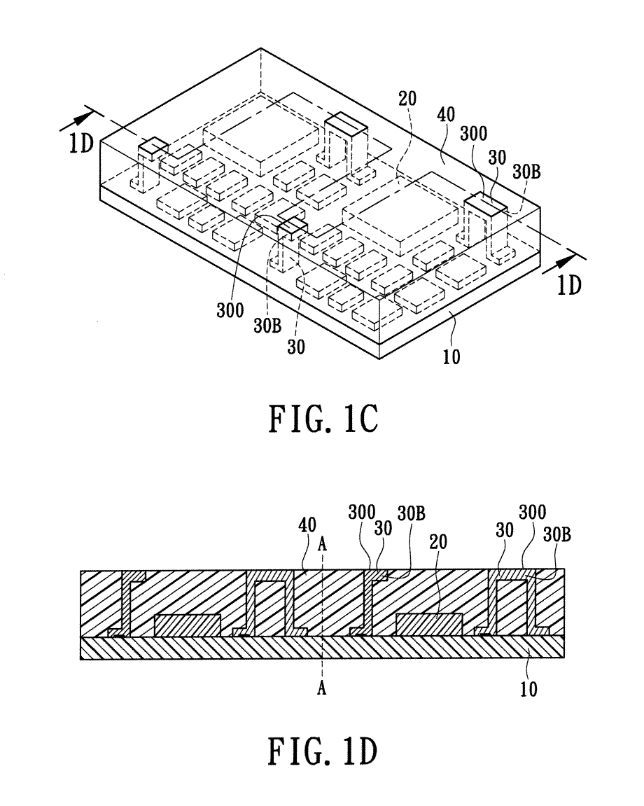

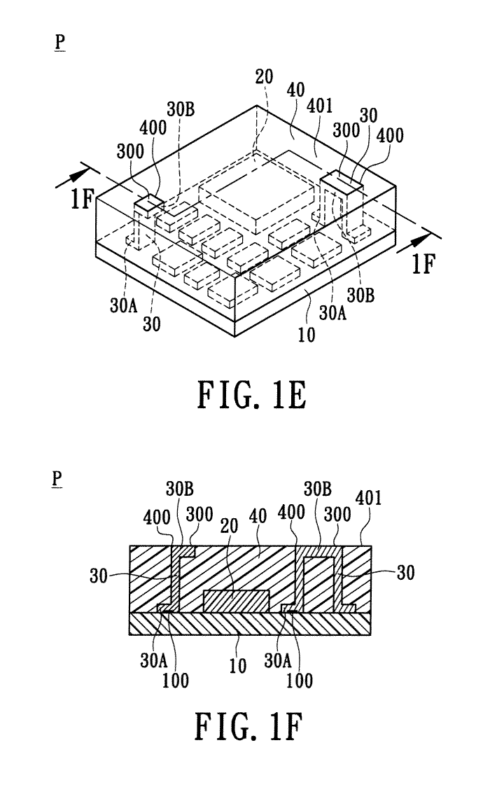

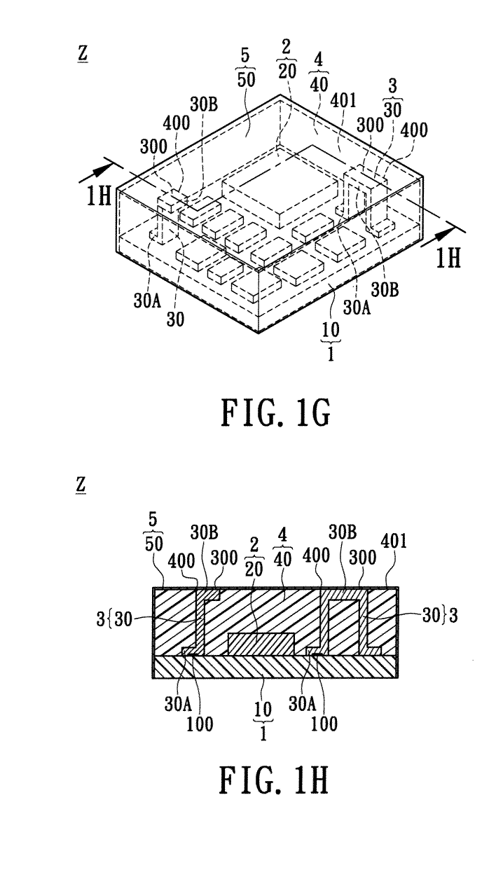

Referring to FIGS. 1 and 1A to 1H, the first embodiment of the instant disclosure provides a method for making a module IC package structure Z with electrical shield function, comprising the steps of:

The step S100 is that: referring to FIGS. 1, 1A and 1B, providing at least one circuit substrate 10 having at least four grounding pads 100. For example, a predetermined pattern (not shown) and four or more than four grounding pads 100 can be formed on the top surface of the circuit substrate 10 in advance.

The step S102 is that: referring to FIGS. 1, 1A and 1B, placing a plurality of electronic elements 20 on the circuit substrate 10 to electrically connect to the circuit substrate 10. For example, each electronic element 20 may be a resistance, a capacitance, an inductance, a function chip having a predetermined function or a semiconductor chip having a predetermined function etc. Thus, any type of electronic component can be applied to the instant disclosure.

The step S104 is that: referring to FIGS. 1, 1A and 1B, placing at least four elastic conductive elements 30 (such as piece-type conductive element) on the circuit substrate 10, wherein each elastic conductive element 30 has a first end portion 30A electrically connected to each grounding pad 100 and a second end portion 30B. For example, each grounding pad 100 is disposed on the top surface of the circuit substrate 10, thus the bottom surface of the first end portion 30A of each elastic conductive element 30 can electrically contact each grounding pad 100. Each elastic conductive element 30 may be a one-pin type elastic piece that uses one pin to contact each grounding pad 100 or a two-pin type elastic piece that uses two pins to respectively contact every two grounding pads 100. In addition, each elastic conductive element 30 may be a conductive metal or an electronic component with conductive function, and the number of the elastic conductive elements 30 is merely an example and is not meant to the instant disclosure.

The step S106 is that: referring to FIGS. 1, 1C and 1D, forming a package resin body 40 on the circuit substrate 10 to cover the electronic elements 20 and one part of the elastic conductive element 30, wherein the top surface 300 of the second end portion 30B of each elastic conductive element 30 is exposed from the package resin 40. For example, when the electronic elements 20 and one part of the elastic conductive element 30 are covered with the package resin body 40, only the top surface 300 of the second end portion 30B of each elastic conductive element 30 is exposed from the package resin body 40, thus the top surface 300 may be flush with the top surface of the package resin body 40.

The step S108 is that: referring to FIGS. 1, 1E and 1F, cutting the package resin body 40 and the circuit substrate 10 along the A-A line of FIG. 1D to form two package units P, wherein each package unit P includes a circuit substrate 10, a plurality of electronic elements 20 electrically connected to the circuit substrate 10 and two elastic conductive elements 30 disposed on the circuit substrate 10, and the circuit substrate 10 includes two grounding pads 100 respectively electrically connected to the two elastic conductive elements 30. For example, the package resin body 40 has two openings 400, the top surface 300 of the second end portion 30B of each elastic conductive element 30 is exposed by each opening 400, and the top surface 300 of the second end portion 30B of each elastic conductive element 30 is flush with the top surface 401 of the package resin body 40.

The step S110 is that: referring to FIGS. 1, 1G and 1H, forming a metal shielding layer 50 on the outer surface of the package resin body 40 and the exposed top surface 300 of the second end portion 30B of each elastic conductive element 30 to electrically contact the second end portion 30B of each elastic conductive element 30. For example, each opening 400 of the package resin body 40 is covered by the metal shielding layer 50, and the metal shielding layer 50 electrically contacts the top surface 300 of the second end portion 30B of each elastic conductive element 30. In addition, the metal shielding layer 50 may be formed by spraying to from a conductive spray layer, by sputtering to form a conductive sputtering layer, by printing to form a conductive printing layer, or by electroplating to form a conductive electroplating layer etc.

In conclusion, referring to FIGS. 1G and 1H, the first embodiment of the instant disclosure provides a module IC package structure Z with electrical shield function, comprising: a substrate unit 1, an electronic unit 2, a conductive unit 3, a package unit 4 and a shielding unit 5. The substrate unit 1 includes at least one circuit substrate 10 having at least one grounding pad 100 (using four grounding pads 100 is an example in the first embodiment). The electronic unit 2 includes a plurality of electronic elements 20 disposed on and electrically connected to the circuit substrate 10. The conductive unit 3 includes at least one elastic conductive element 30 (using four elastic conductive elements 30 is an example in the first embodiment) disposed on the circuit substrate 10, and the elastic conductive element 30 has a first end portion 30A electrically connected to the grounding pad 100. The package unit 4 includes a package resin body 40 disposed on the circuit substrate 10 to cover the electronic elements 20 and one part of the elastic conductive element 30, and the elastic conductive element 30 has a second end portion 30B is exposed from the package resin body 40. The shielding unit 5 includes a metal shielding layer 50 formed on the outer surface of the package resin body 40 to electrically contact the second end portion 30B of the elastic conductive element 30.

For example, the grounding pad 100 is disposed on the top surface of the circuit substrate 10, thus the bottom surface of the first end portion 30A electrically contacts the grounding pad 100. The package resin body 40 has an opening 400 formed on the top surface thereof for exposing the second end portion 30B of the elastic conductive element 30. The top surface 300 of the second end portion 30B of the elastic conductive element 30 is flush with the top surface 401 of the package resin body 40. The opening 400 of the package resin body 40 is covered by the metal shielding layer 50, and the metal shielding layer 50 covers and electrically contacts the top surface 300 of the second end portion 30B. In addition, the metal shielding layer 50 may be a conductive spray layer, a conductive sputtering layer, a conductive printing layer or a conductive electroplating layer etc. according to different requirements.

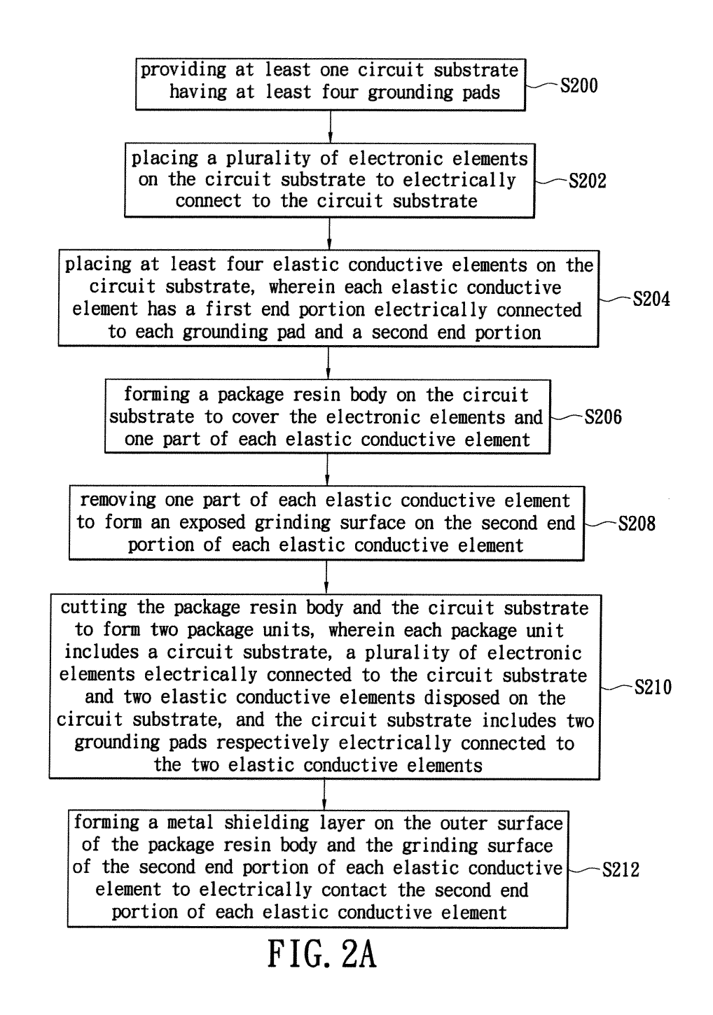

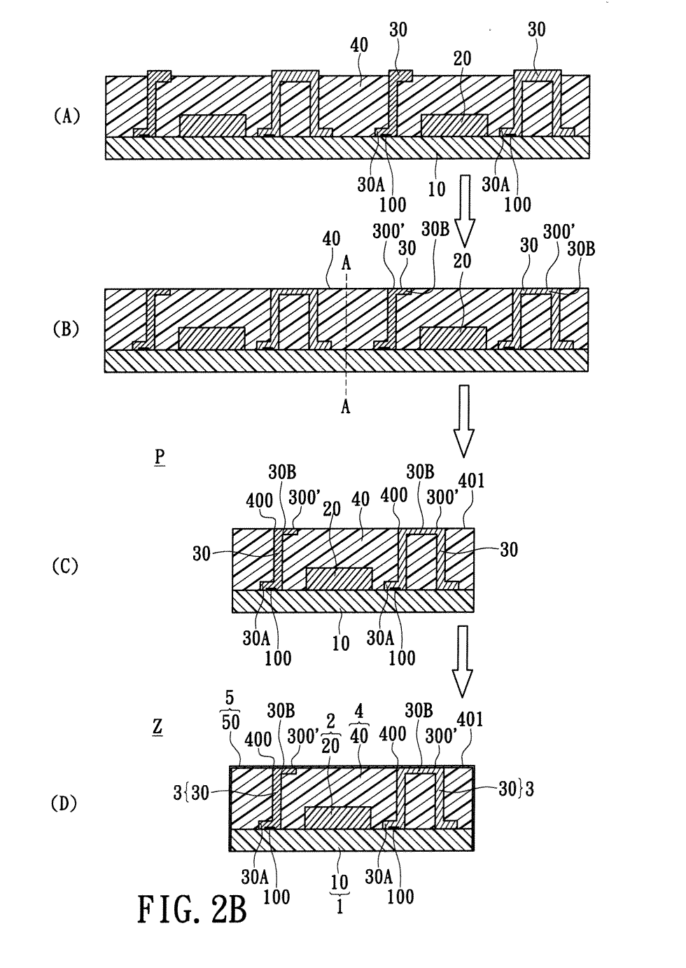

Referring to FIGS. 2A and 2B, the second embodiment of the instant disclosure provides a method for making a module IC package structure Z with electrical shield function, comprising the steps of:

The step S200 is that: referring to FIGS. 2A and 2B(A), providing at least one circuit substrate 10 having at least four grounding pads 100.

The step S202 is that: referring to FIGS. 2A and 2B(A), placing a plurality of electronic elements 20 on the circuit substrate 10 to electrically connect to the circuit substrate 10.

The step S204 is that: referring to FIGS. 2A and 2B(A), placing at least four elastic conductive elements 30 on the circuit substrate 10, wherein each elastic conductive element 30 has a first end portion 30A electrically connected to each grounding pad 100 and a second end portion 30B.

The step S206 is that: referring to FIGS. 2A and 2B(A), forming a package resin body 40 on the circuit substrate 10 to cover the electronic elements 20 and one part of each elastic conductive element 30.

The step S208 is that: referring to FIGS. 2A and 2B(B), removing (such as grinding) one part of each elastic conductive element 30 to form an exposed grinding (or cutting, removing) surface 300′ on the second end portion 30B of each elastic conductive element 30.

The step S210 is that: referring to FIGS. 2A and 2B(C), cutting the package resin body 40 and the circuit substrate 10 along the A-A line of FIG. 2B(B) to form two package units P, wherein each package unit P includes a circuit substrate 10, a plurality of electronic elements 20 electrically connected to the circuit substrate 10 and two elastic conductive elements 30 disposed on the circuit substrate 10, and the circuit substrate 10 includes two grounding pads 100 respectively electrically connected to the two elastic conductive elements 30. For example, the package resin body 40 has two openings 400, the exposed grinding surface 300′ of the second end portion 30B of each elastic conductive element 30 is exposed by each opening 400, and the exposed grinding surface 300′ of the second end portion 30B of each elastic conductive element 30 is flush with the top surface 401 of the package resin body 40.

The step S212 is that: referring to FIGS. 2A and 2B(D), forming a metal shielding layer 50 on the outer surface of the package resin body 40 and the grinding surface 300′ of the second end portion 30B of each elastic conductive element 30 to electrically contact the second end portion 30B of each elastic conductive element 30. For example, each opening 400 of the package resin body 40 is covered by the metal shielding layer 50, and the metal shielding layer 50 electrically contacts the grinding surface 300′ of the second end portion 30B of each elastic conductive element 30.

In conclusion, referring to FIG. 2B(D), the second embodiment of the instant disclosure provides a module IC package structure Z with electrical shield function, comprising: a substrate unit 1, an electronic unit 2, a conductive unit 3, a package unit 4 and a shielding unit 5. The substrate unit 1 includes at least one circuit substrate 10 having at least one grounding pad 100 (using four grounding pads 100 is an example in the second embodiment). The electronic unit 2 includes a plurality of electronic elements 20 disposed on and electrically connected to the circuit substrate 10. The conductive unit 3 includes at least one elastic conductive element 30 (using four elastic conductive elements 30 is an example in the second embodiment) disposed on the circuit substrate 10, and the elastic conductive element 30 has a first end portion 30A electrically connected to the grounding pad 100. The package unit 4 includes a package resin body 40 disposed on the circuit substrate 10 to cover the electronic elements 20 and one part of the elastic conductive element 30, and the elastic conductive element 30 has a second end portion 30B is exposed from the package resin body 40. The shielding unit 5 includes a metal shielding layer 50 formed on the outer surface of the package resin body 40 to electrically contact the second end portion 30B of the elastic conductive element 30.

For example, the grounding pad 100 is disposed on the top surface of the circuit substrate 10, thus the bottom surface of the first end portion 30A electrically contacts the grounding pad 100. The package resin body 40 has an opening 400 formed on the top surface thereof for exposing the second end portion 30B of the elastic conductive element 30. The grinding surface 300′ of the second end portion 30B of the elastic conductive element 30 is flush with the top surface 401 of the package resin body 40. The opening 400 of the package resin body 40 is covered by the metal shielding layer 50, and the metal shielding layer 50 covers and electrically contacts the grinding surface 300′ of the second end portion 30B. In addition, the metal shielding layer 50 may be a conductive spray layer, a conductive sputtering layer, a conductive printing layer or a conductive electroplating layer etc. according to different requirements.

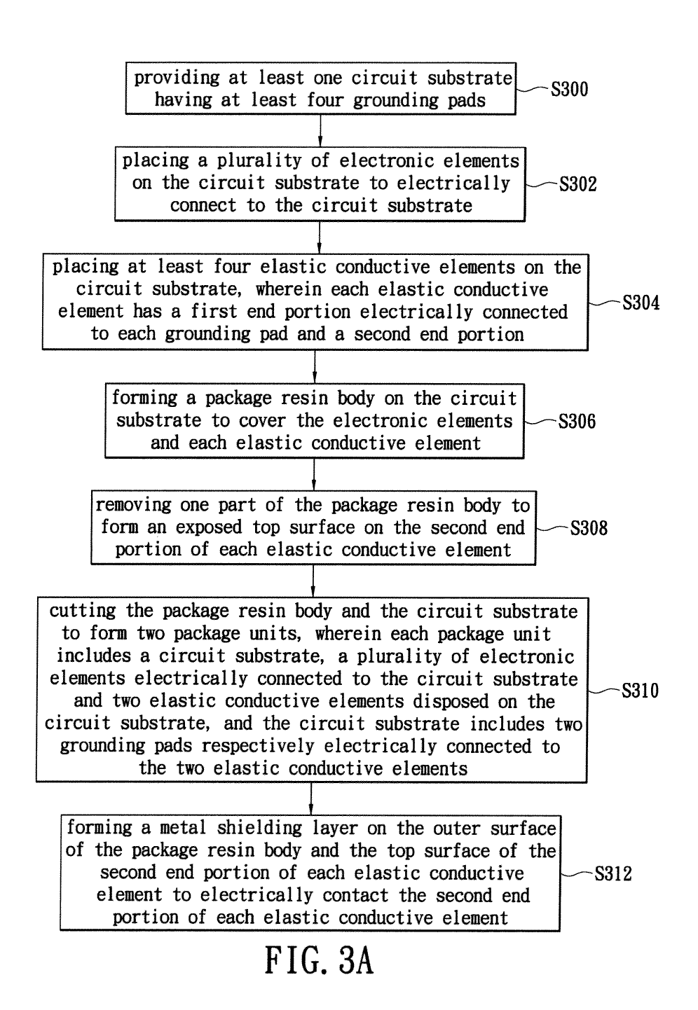

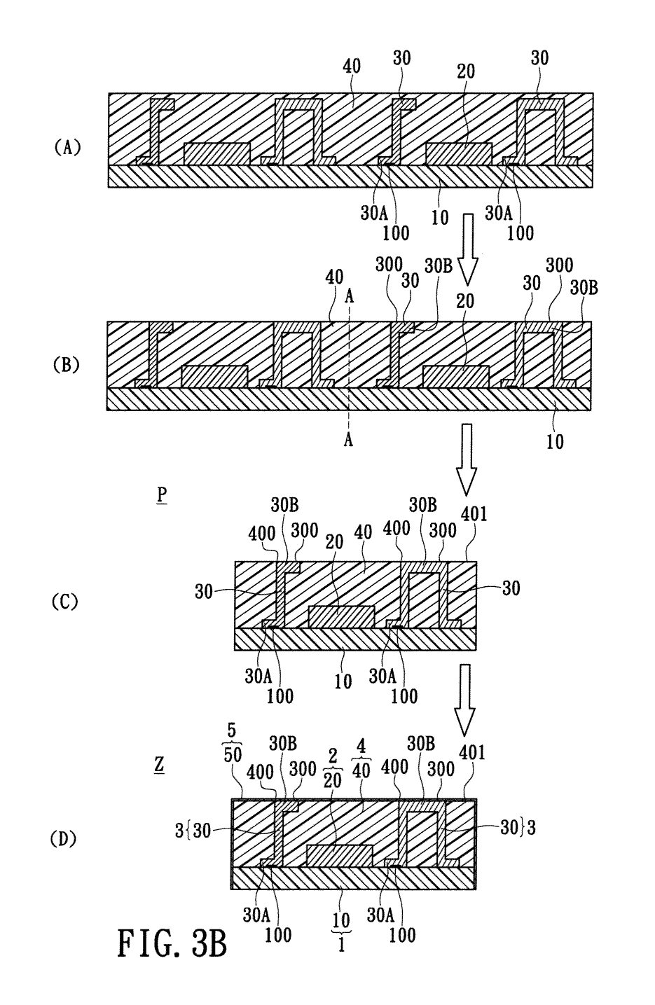

Referring to FIGS. 3A and 3B, the third embodiment of the instant disclosure provides a method for making a module IC package structure Z with electrical shield function, comprising the steps of:

The step S300 is that: referring to FIGS. 3A and 3B(A), providing at least one circuit substrate 10 having at least four grounding pads 100.

The step S302 is that: referring to FIGS. 3A and 3B(A), placing a plurality of electronic elements 20 on the circuit substrate 10 to electrically connect to the circuit substrate 10.

The step S304 is that: referring to FIGS. 3A and 3B(A), placing at least four elastic conductive elements 30 on the circuit substrate 10, wherein each elastic conductive element 30 has a first end portion 30A electrically connected to each grounding pad 100 and a second end portion 30B.

The step S306 is that: referring to FIGS. 3A and 3B(A), forming a package resin body 40 on the circuit substrate 10 to cover the electronic elements 20 and each elastic conductive element 30.

The step S308 is that: referring to FIGS. 3A and 3B(B), removing one part of the package resin body 40 to form an exposed top surface 300 on the second end portion 30B of each elastic conductive element 30.

The step S310 is that: referring to FIGS. 3A and 3B(C), cutting the package resin body 40 and the circuit substrate 10 along the A-A line of FIG. 3B(B) to form two package units P, wherein each package unit P includes a circuit substrate 10, a plurality of electronic elements 20 electrically connected to the circuit substrate 10 and two elastic conductive elements 30 disposed on the circuit substrate 10, and the circuit substrate 10 includes two grounding pads 100 respectively electrically connected to the two elastic conductive elements 30. For example, the package resin body 40 has two openings 400, the exposed top surface 300 of the second end portion 30B of each elastic conductive element 30 is exposed by each opening 400, and the exposed top surface 300 of the second end portion 30B of each elastic conductive element 30 is flush with the top surface 401 of the package resin body 40.

The step S312 is that: referring to FIGS. 3A and 3B(D), forming a metal shielding layer 50 on the outer surface of the package resin body 40 and the top surface 300 of the second end portion 30B of each elastic conductive element 30 to electrically contact the second end portion 30B of each elastic conductive element 30. For example, each opening 400 of the package resin body 40 is covered by the metal shielding layer 50, and the metal shielding layer 50 electrically contacts the top surface 300 of the second end portion 30B of each elastic conductive element 30.

In conclusion, referring to FIG. 3B(D), the third embodiment of the instant disclosure provides a module IC package structure Z with electrical shield function, comprising: a substrate unit 1, an electronic unit 2, a conductive unit 3, a package unit 4 and a shielding unit 5. The substrate unit 1 includes at least one circuit substrate 10 having at least one grounding pad 100 (using four grounding pads 100 is an example in the third embodiment). The electronic unit 2 includes a plurality of electronic elements 20 disposed on and electrically connected to the circuit substrate 10. The conductive unit 3 includes at least one elastic conductive element 30 (using four elastic conductive elements 30 is an example in the third embodiment) disposed on the circuit substrate 10, and the elastic conductive element 30 has a first end portion 30A electrically connected to the grounding pad 100. The package unit 4 includes a package resin body 40 disposed on the circuit substrate 10 to cover the electronic elements 20 and one part of the elastic conductive element 30, and the elastic conductive element 30 has a second end portion 30B is exposed from the package resin body 40. The shielding unit 5 includes a metal shielding layer 50 formed on the outer surface of the package resin body 40 to electrically contact the second end portion 30B of the elastic conductive element 30.

For example, the grounding pad 100 is disposed on the top surface of the circuit substrate 10, thus the bottom surface of the first end portion 30A electrically contacts the grounding pad 100. The package resin body 40 has an opening 400 formed on the top surface thereof for exposing the second end portion 30B of the elastic conductive element 30. The top surface 300 of the second end portion 30B of the elastic conductive element 30 is flush with the top surface 401 of the package resin body 40. The opening 400 of the package resin body 40 is covered by the metal shielding layer 50, and the metal shielding layer 50 covers and electrically contacts the top surface 300 of the second end portion 30B. In addition, the metal shielding layer 50 may be a conductive spray layer, a conductive sputtering layer, a conductive printing layer or a conductive electroplating layer etc. according to different requirements.

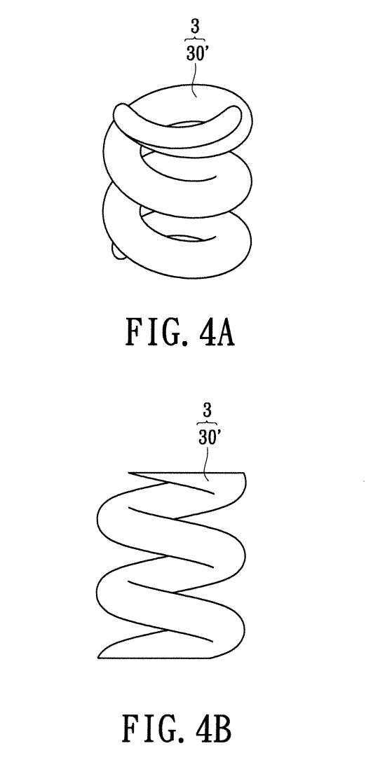

Referring to FIGS. 4A and 4B, each piece-type elastic conductive element 30 of the conductive unit 3 can be replaced by spiral conductive element 30′. In other words, not only the piece-type elastic conductive element 30 or the spiral conductive element 30′ can be used to electrically connect between the grounding pad 100 and the metal shielding layer 50, but also any type of elastic conductive element can be applied to the instant disclosure.

In conclusion, the metal shielding layer on the package resin body can electrically contact the grounding pad of the circuit substrate through the at least one elastic conductive element, thus the instant disclosure can generate the electrical shield function to prevent the electronic elements from being interfered by external environment.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A module IC package structure, comprising:
a substrate unit including at least one circuit substrate having at least one grounding pad;
an electronic unit including a plurality of electronic elements disposed on and electrically connected to the circuit substrate;
a conductive unit including at least one elastic conductive element disposed on the circuit substrate, wherein the elastic conductive element has a first end portion electrically connected to the grounding pad;
a package unit including a package resin body disposed on the circuit substrate to cover the electronic elements and one part of the elastic conductive element, wherein the elastic conductive element has a second end portion is exposed; and
a shielding unit including a metal shielding layer formed on the outer surface of the package resin body to electrically contact the second end portion of the elastic conductive element.

2. The module IC package structure of claim 1, wherein the grounding pad is disposed on the top surface of the circuit substrate, and the bottom surface of the first end portion electrically contacts the grounding pad.

3. The module IC package structure of claim 1, wherein the package resin body has an opening formed on the top surface thereof for exposing the second end portion of the elastic conductive element, and the opening of the package resin body is covered by the metal shielding layer.

4. The module IC package structure of claim 1, wherein the second end portion of the elastic conductive element has a top surface flush with the top surface of the package resin body, and the metal shielding layer covers and electrically contacts the top surface of the second end portion.

5. The module IC package structure of claim 1, wherein the second end portion of the elastic conductive element has a grinding surface flush with the top surface of the package resin body, and the metal shielding layer covers and electrically contacts the grinding surface of the second end portion.

6. The module IC package structure of claim 1, wherein the metal shielding layer is a conductive spray layer, a conductive sputtering layer, a conductive printing layer or a conductive electroplating layer.

7. The module IC package structure of claim 1, wherein each elastic conductive element is a conductive metal or an electronic component with conductive function.

8. A method for making a module IC package structure, comprising the steps of:
providing at least one circuit substrate having at least one grounding pad;
placing a plurality of electronic elements on the circuit substrate to electrically connect to the circuit substrate;
placing at least one elastic conductive element on the circuit substrate, wherein the elastic conductive element has a first end portion electrically connected to the grounding pad and a second end portion;
forming a package resin body on the circuit substrate to cover the electronic elements and the elastic conductive element;
removing one part of the package resin body to form an exposed top surface on the second end portion of the elastic conductive element or removing one part of the elastic conductive element to form an exposed grinding surface on the second end portion of the elastic conductive element; and
forming a metal shielding layer on the outer surface of the package resin body and the exposed top or grinding surface of the second end portion of the elastic conductive element to electrically contact the second end portion of the elastic conductive element.

9. The method of claim 8, wherein the grounding pad is disposed on the top surface of the circuit substrate, and the bottom surface of the first end portion electrically contacts the grounding pad.

10. The method of claim 8, wherein the package resin body has an opening formed on the top surface thereof for exposing the second end portion of the elastic conductive element, and the opening of the package resin body is covered by the metal shielding layer.

11. The method of claim 8, wherein the exposed top or grinding surface of the second end portion of the elastic conductive element is flush with the top surface of the package resin body, and the metal shielding layer electrically contacts the exposed top or grinding surface of the second end portion of the elastic conductive element.

12. The method of claim 8, wherein the metal shielding layer is formed by spraying, sputtering, printing or electroplating.

13. A method for making a module IC package structure with electrical shield function, comprising the steps of:
providing at least one circuit substrate having at least one grounding pad;
placing a plurality of electronic elements on the circuit substrate to electrically connect to the circuit substrate;
placing at least one elastic conductive element on the circuit substrate, wherein the elastic conductive element has a first end portion electrically connected to the grounding pad and a second end portion;
forming a package resin body on the circuit substrate to cover the electronic elements and one part of the elastic conductive element, wherein the top surface of the second end portion of the elastic conductive element is exposed from the package resin; and
forming a metal shielding layer on the outer surface of the package resin body and the top surface of the second end portion of the elastic conductive element to electrically contact the second end portion of the elastic conductive element.

14. The method of claim 13, wherein the grounding pad is disposed on the top surface of the circuit substrate, and the bottom surface of the first end portion electrically contacts the grounding pad.

15. The method of claim 13, wherein the package resin body has an opening formed on the top surface thereof for exposing the second end portion of the elastic conductive element, and the opening of the package resin body is covered by the metal shielding layer.

16. The method of claim 13, wherein the top surface of the second end portion of the elastic conductive element is flush with the top surface of the package resin body, and the metal shielding layer electrically contacts the top surface of the second end portion of the elastic conductive element.

17. The method of claim 13, wherein the metal shielding layer is formed by spraying, sputtering, printing or electroplating.
